(19) United States
(12) Patent Application Publication
(10) Pub. No.: US 2024/0044937 A1
(43) Pub. Date: Feb. 8, 2024

(54) ACCELERATION SENSOR

(71) Applicant: ROHM CO., LTD., Kyoto (JP)

(72) Inventor: Hiroki MIYABUCHI, Kyoto (JP)

(73) Assignee: ROHM CO., LTD., Kyoto (JP)

(21) Appl. No.: 18/488,793

(22) Filed: Oct. 17, 2023

Related U.S. Application Data
(63) Continuation of application No. PCT/JP2022/021988, filed on May 30, 2022.

(30) Foreign Application Priority Data
Jun. 16, 2021 (JP) 2021-100295

(51) Int. Cl. G01P 15/18; G01P 15/125

(52) U.S. Cl. CPC G01P 15/18; G01P 15/125

(57) ABSTRACT

An acceleration sensor includes a semiconductor substrate that has a cavity formed in an interior, a fixed structure that includes a fixed electrode supported by the semiconductor substrate in a state of floating with respect to the cavity, and a movable structure that includes a movable electrode supported by the semiconductor substrate via an elastic structure in a state of floating with respect to the cavity and displacing with respect to the fixed electrode. The elastic structure includes a first end portion supported by the semiconductor substrate, a second end portion connected to the movable structure, and an intermediate portion connecting the first end portion and the second end portion and has a rectilinearly-extending rectilinear portion at least at a portion of the intermediate portion and the rectilinear portion includes a plurality of rectilinear frames extending in parallel to each other in a direction in which the rectilinear portion extends.

### CROSS REFERENCE TO RELATED APPLICATIONS

The present application is a bypass continuation of International Patent Application No. PCT/JP2022/021988, filed on May 30, 2022, which corresponds to Japanese Patent Application No. 2021-100295 filed on Jun. 16, 2021 with the Japan Patent Office, and the entire disclosure of this application is incorporated herein by reference.

### TECHNICAL FIELD

The present disclosure relates to an acceleration sensor.

### BACKGROUND ART

Acceleration sensors for measuring an acceleration that acts on an object are widely used to ascertain, for example, an orientation or movement, vibration state, etc., of an object. Also, with acceleration sensors, there is a strong demand for miniaturization. To answer such a demand, miniaturization of acceleration sensors is being carried out using so-called MEMS (micro electro mechanical system) technology. For example, an acceleration sensor of an electrostatic capacitance type that uses MEMS technology is disclosed in Japanese Patent Application Publication No. 2019-49434.

It is also being demanded that acceleration sensors be made wide in range of detectable acceleration such that a high acceleration can be detected and also be made broad-band such as to enable detection even when an acceleration change occurs at a high frequency. To improve these two characteristics, a resonance frequency of vibration of a movable portion of an acceleration sensor must be made high.

The aforementioned as well as yet other objects, features, and effects of the present disclosure will be made clear by the following description of the preferred embodiments made with reference to the accompanying drawings.

### BRIEF DESCRIPTION OF DRAWINGS

FIG. 1 is an illustrative plan view showing an acceleration sensor according to a preferred embodiment of the present disclosure.

FIG. 2 is an illustrative plan view mainly showing an X-axis sensor.

FIG. 3 is an enlarged plan view of principal portions of FIG. 2.

FIG. 4 is an enlarged illustrative sectional view taken along line IV-IV of FIG. 3.

FIG. 5A is an enlarged illustrative plan view showing a spring portion used in the X-axis sensor shown in FIG. 3.

FIG. 5B is an enlarged illustrative plan view showing a first modification example of a spring portion.

FIG. 5C is an enlarged illustrative plan view showing a second modification example of a spring portion.

FIG. 5D is an enlarged illustrative plan view showing a spring portion used in an X-axis sensor according to a reference example shown in FIG. 6.

FIG. 6 is an enlarged illustrative plan view of principal portions showing the reference example of the X-axis sensor.

FIG. 7A is a graph showing a relationship of frequency and amplitude of vibration of the X-axis sensor of the preferred embodiment.

FIG. 7B is a graph showing a relationship of frequency and amplitude of vibration of the X-axis sensor according to the reference example.

FIG. 8 is an illustrative plan view showing a modification example of an X-axis sensor.

FIG. 9A is an enlarged illustrative plan view showing a spring portion used in the X-axis sensor according to the modification example.

FIG. 9B is an enlarged illustrative plan view showing a reference example of a spring portion.

FIG. 10 is an illustrative plan view showing a Z-axis sensor.

FIG. 11A is an enlarged plan view of principal portions of FIG. 10.

FIG. 11B is an enlarged plan view of principal portions showing a reference example of a Z-axis sensor.

FIG. 12 is a schematic view showing positional relationships in a Z-axis direction of fixed electrodes and movable electrodes of Z-axis sensors when an acceleration in the Z-axis direction is not acting and positional relationships in the Z-axis direction of the fixed electrodes and the movable electrodes of the Z-axis sensors when an acceleration in the Z-axis direction acts.

FIG. 13A is a graph showing a relationship of frequency and amplitude of vibration of the Z-axis sensor of the preferred embodiment.

FIG. 13B is a graph showing a relationship of frequency and amplitude of vibration of the Z-axis sensor according to the reference example.

FIG. 14 is an illustrative plan view showing a modification example of a Z-axis sensor.

### DESCRIPTION OF EMBODIMENTS

A preferred embodiment of the present disclosure provides an acceleration sensor including a semiconductor substrate that has a cavity formed in an interior, a fixed structure that includes a fixed electrode supported by the semiconductor substrate in a state of floating with respect to the cavity, and a movable structure that includes a movable electrode supported by the semiconductor substrate via an elastic structure in a state of floating with respect to the cavity and displacing with respect to the fixed electrode and where the elastic structure includes a first end portion supported by the semiconductor substrate, a second end portion connected to the movable structure, and an intermediate portion connecting the first end portion and the second end portion and has a rectilinearly-extending rectilinear portion at least at a portion of the intermediate portion and the rectilinear portion includes a plurality of rectilinear frames extending in parallel to each other in a direction in which the rectilinear portion extends.

With this arrangement, a resonance frequency of vibration of a movable portion of the acceleration sensor can be made high.

In the preferred embodiment of the present disclosure, the rectilinear portion includes a plurality of reinforcing frames that are installed between the plurality of rectilinear frames included in the rectilinear portion.

In the preferred embodiment of the present disclosure, the rectilinear portion includes a plurality of reinforcing frames that are installed between the plurality of rectilinear frames included in the rectilinear portion such that between the plurality of rectilinear frames, spaces of triangular shape are repeated along the rectilinear frames.

In the preferred embodiment of the present disclosure, the rectilinear portion includes a first rectilinear portion and a second rectilinear portion that extend in parallel to each other and a third rectilinear portion that links one ends of the first rectilinear portion and the second rectilinear portion to each other.

In the preferred embodiment of the present disclosure, the first rectilinear portion, the second rectilinear portion, and the third rectilinear portion each include at least one reinforcing frame that is installed between the plurality of rectilinear frames included therein.

In the preferred embodiment of the present disclosure, the rectilinear portion includes a rectilinear portion that is parallel to a direction in which the movable electrode extends.

In the preferred embodiment of the present disclosure, the fixed electrode includes a pair of fixed electrodes that, at an interval in a predetermined first direction, extend in parallel to each other in a second direction orthogonal to the first direction and the movable electrode includes a pair of movable electrodes that are disposed between the pair of fixed electrodes and, at an interval in the first direction, extend in parallel to each other in the second direction.

In the preferred embodiment of the present disclosure, the fixed electrode includes a plurality of fixed electrodes that are formed in a comb-teeth shape in plan view, the movable electrode includes a plurality of movable electrode pairs that are formed in a comb-teeth shape in plan view, the plurality of movable electrode pairs are disposed such as to contactlessly mesh with the plurality of fixed electrodes, and each movable electrode pair includes two of the movable electrodes that respectively face the fixed electrodes at respective sides of the movable electrode pair and extend in parallel to each other.

In the preferred embodiment of the present disclosure, a lateral cross-sectional shape of the fixed electrode and a lateral cross-sectional shape of the movable electrode are each a quadrilateral shape that is elongate in an up/down direction.

In the preferred embodiment of the present disclosure, the elastic structure includes one of the rectilinear portion and a tapered portion that is connected to one end of the rectilinear portion, the rectilinear portion is constituted of two of the rectilinear frames that are parallel to each other, and the tapered portion is constituted of two connection frames that extend obliquely outward with respect to the two rectilinear frames from respective one end portions of the two rectilinear frames such that an interval between each other widens gradually.

In the preferred embodiment of the present disclosure, the rectilinear portion is parallel to a direction in which the movable electrode extends or is parallel to a direction that is a direction along a front surface of the semiconductor substrate and orthogonal to the direction in which the movable electrode extends.

In the preferred embodiment of the present disclosure, the fixed electrode includes a plurality of fixed electrodes that are formed in a comb-teeth shape in plan view, the movable electrode includes a plurality of movable electrodes that are formed in a comb-teeth shape in plan view, and the plurality of movable electrodes are disposed such as to contactlessly mesh with the plurality of fixed electrodes.

In the preferred embodiment of the present disclosure, a lateral cross-sectional shape of the fixed electrode and a lateral cross-sectional shape of the movable electrode are each a quadrilateral shape that is elongate in an up/down direction.

In the preferred embodiment of the present disclosure, one of either of the fixed electrode and the movable electrode is disposed in a state of being shifted downward with respect to the other.

In the following, preferred embodiments of the present disclosure shall be described in detail with reference to the accompanying drawings.

[1] Overall arrangement of acceleration sensor

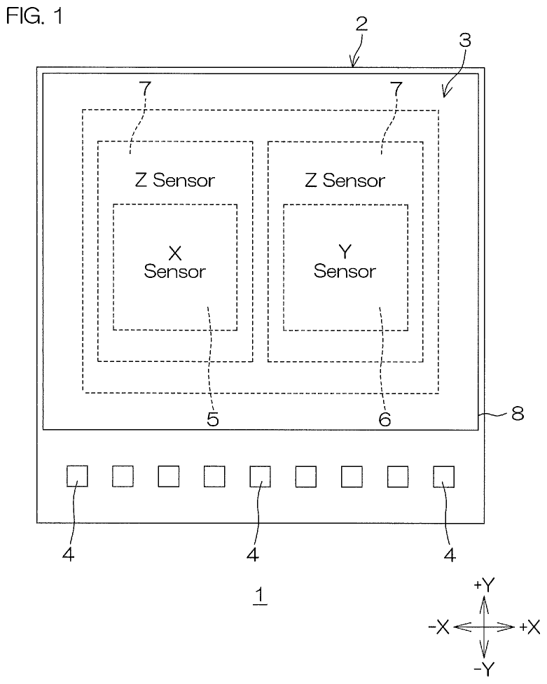

FIG. 1 is an illustrative plan view showing an acceleration sensor according to a preferred embodiment of the present disclosure.

For convenience of description, a +X direction, a −X direction, a +Y direction, a −Y direction, a +Z direction, and a −Z direction shown in FIG. 1 to FIG. 4 are used at times in the following description. The +X direction is a predetermined direction along a front surface of a semiconductor substrate 2 in plan view and the +Y direction is a direction along the front surface of the semiconductor substrate 2 and is a direction that is orthogonal to the +X direction in plan view. The +Z direction is a direction along a thickness of the semiconductor substrate 2 and is a direction that is orthogonal to the +X direction and the +Y direction.

The −X direction is a direction opposite to the +X direction. The −Y direction is a direction opposite to the +Y direction. The −Z direction is a direction opposite to the +Z direction. The +X direction and the −X direction shall be referred to simply as the “X-axis direction” when referred to collectively. The +Y direction and the −Y direction shall be referred to simply as the “Y-axis direction” when referred to collectively. The +Z direction and the −Z direction shall be referred to simply as the “Z-axis direction” when referred to collectively.

An acceleration sensor 1 includes the semiconductor substrate 2 of quadrilateral shape in plan view, a sensor portion 3 disposed at a central portion of the semiconductor substrate 2, and electrode pads 4 that are disposed at a side of the sensor portion 3 of the semiconductor substrate 2. The acceleration sensor 1 is an electrostatic capacitance type acceleration sensor. The semiconductor substrate 2 has the quadrilateral shape having two sides parallel to an X-axis direction and two sides parallel to a Y-axis direction in plan view.

The sensor portion 3 has an X-axis sensor 5, a Y-axis sensor 6, and Z-axis sensors 7 as sensors that respectively detect accelerations acting in directions along three orthogonal axes in three-dimensional space. The X-axis sensor 5 is arranged to detect acceleration acting in the X-axis direction. The Y-axis sensor 6 is arranged to detect acceleration acting in the Y-axis direction. The Z-axis sensors 7 are arranged to detect acceleration acting in a Z-axis direction.

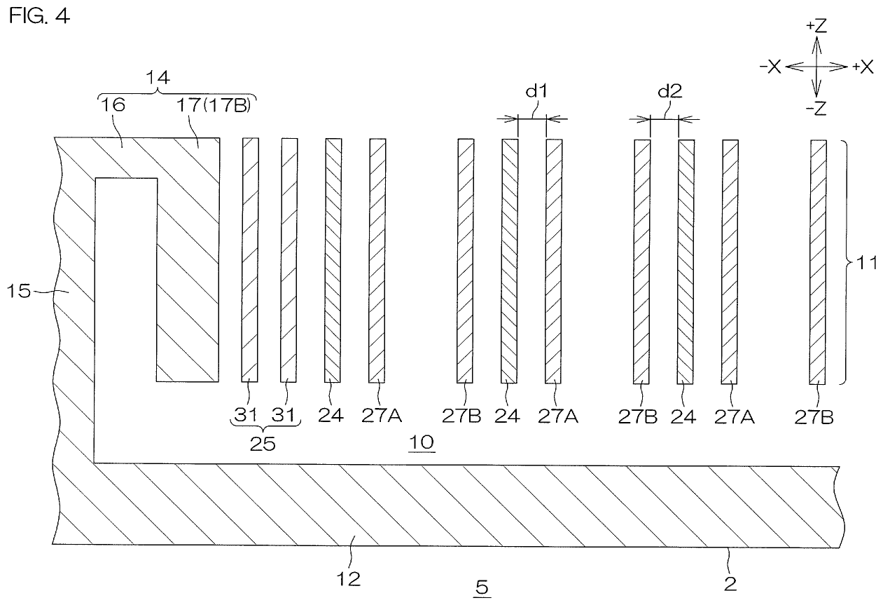

The semiconductor substrate 2 is constituted of a conductive silicon substrate (for example, a low resistance substrate having a resistivity of 5 Ω·m to 500 Ω·m). The semiconductor substrate 2 has a cavity 10 (see FIG. 4) in its interior and the X-axis sensor 5, the Y-axis sensor 6, and the Z-axis sensors 7 are formed in an upper wall (surface layer portion) 11 of the semiconductor substrate 2 having a top surface that demarcates the cavity from a front surface side.

That is, the X-axis sensor 5, the Y-axis sensor 6, and the Z-axis sensors 7 are constituted of portions of the semiconductor substrate 2 and are supported in a state of floating with respect to a bottom wall 12 (see FIG. 4) of the semiconductor substrate 2 having a bottom surface that demarcates the cavity 10 from a rear surface side.

The X-axis sensor 5 and the Y-axis sensor 6 are disposed adjacent to each other at an interval in the X-axis direction. Two Z-axis sensors 7 are disposed such as to surround the X-axis sensor 5 and the Y-axis sensor 6 respectively. In this preferred embodiment, the Y-axis sensor 6 has substantially the same arrangement as the X-axis sensor 5 being rotated by 90° in plan view.

A lid 8 constituted, for example, of a silicon substrate is coupled to the front surface of the semiconductor substrate 2 and thereby, the three types of sensors 5 to 7 are covered and sealed by the lid 8.

The electrode pads 4 are connected to an external electronic component, are arranged to input signals into the respective sensors 5 to 7 or outputting signals from the respective sensors 5 to 7, and a necessary number thereof (nine in FIG. 1) are provided. The external electronic component is, for example, an ASIC (application specific integrated circuit) element.

[2] X-Axis Sensor 5

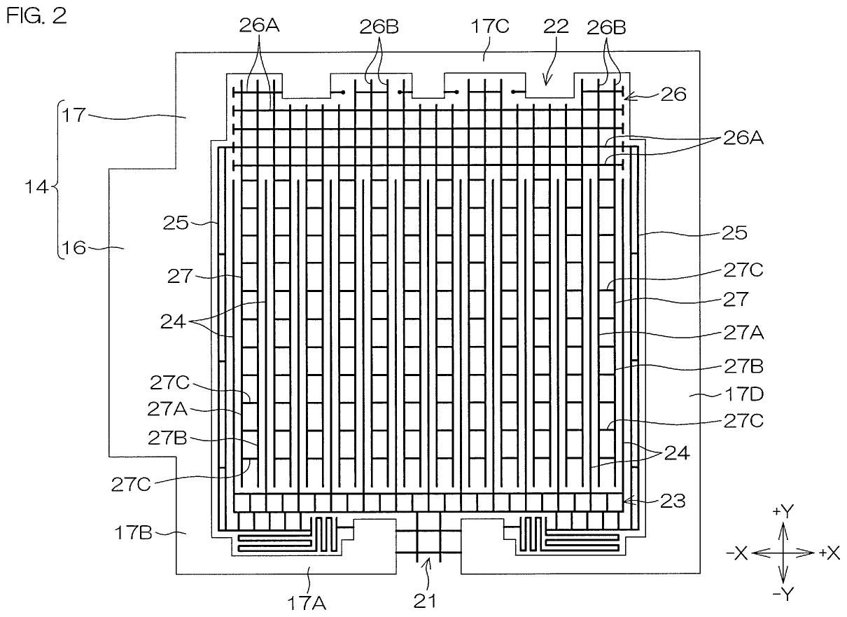

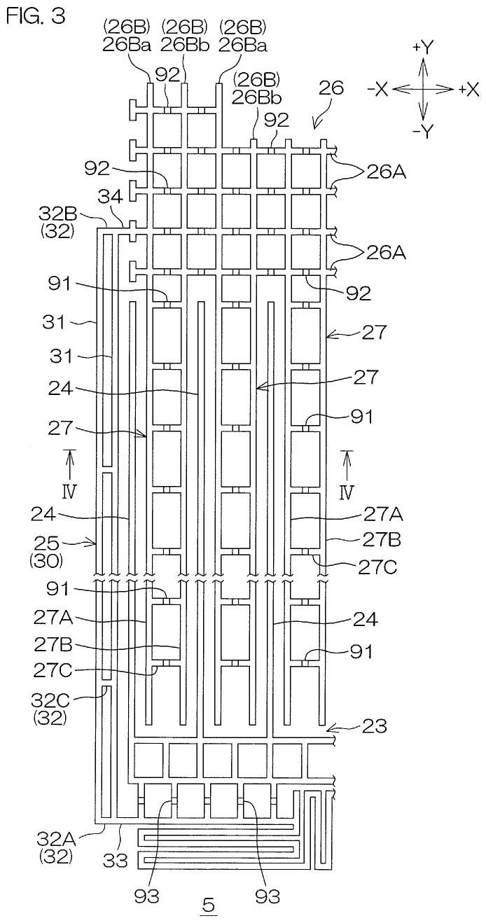

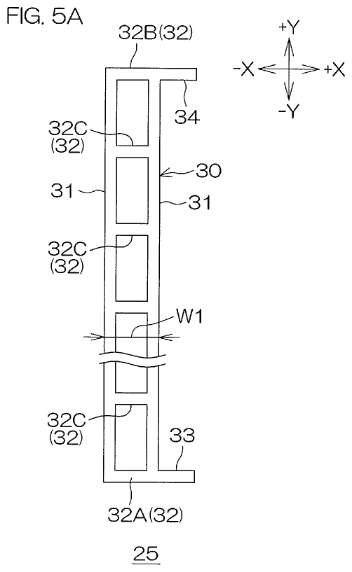

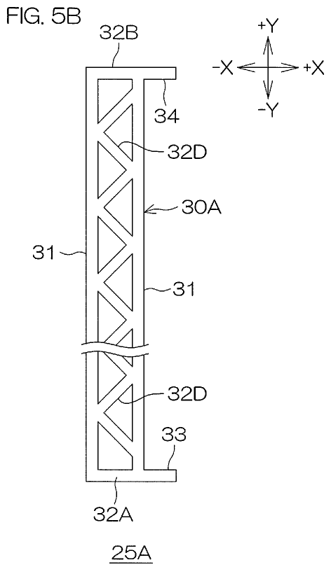

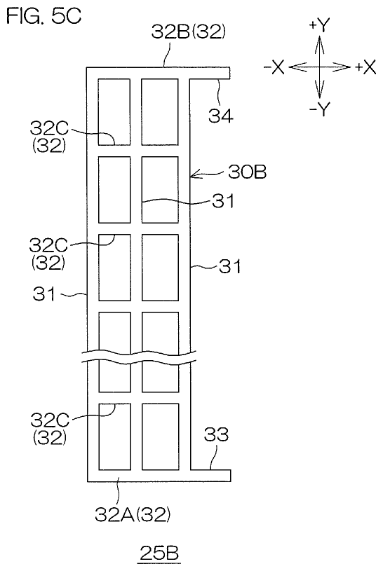

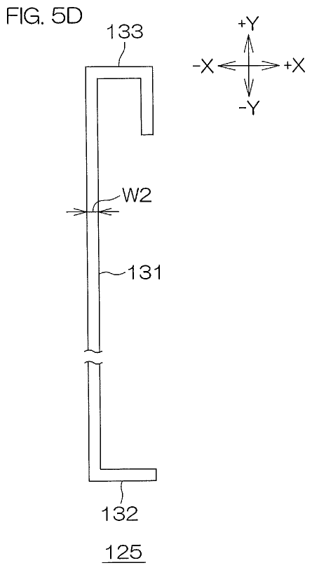

FIG. 2 is an illustrative plan view mainly showing the X-axis sensor. FIG. 3 is an enlarged plan view of principal portions of FIG. 2. FIG. 4 is an enlarged illustrative sectional view taken along line IV-IV of FIG. 3. FIG. 5A is an enlarged illustrative plan view showing a spring portion of FIG. 3.

A supporting portion 14 arranged to support the X-axis sensor 5 in the floating state is formed between the X-axis sensor 5 and the Z-axis sensor 7. The supporting portion 14 integrally includes a supporting base portion 16 that extends toward the X-axis sensor 5 upon crossing the Z-axis sensor 7 from an upper portion of one side wall 15 having a side surface that demarcates the cavity 10 of the semiconductor substrate 2 from a lateral side and an annular portion 17 that surrounds the X-axis sensor 5. The supporting portion 14 is supported by the one side wall 15 of the semiconductor substrate 2 in the state of floating from the bottom wall 12 of the semiconductor substrate 2.

The supporting base portion 16 is of a quadrilateral shape that is long in the Y-axis direction in plan view. The annular portion 17 is of a rectangular annular shape in plan view and includes a first frame portion 17A at the −Y side, a second frame portion 17B at the −X side, a third frame portion 17C at the +Y side, and a fourth frame portion 17D at the +X side. However, the first frame portion 17A is interrupted at a length central portion. A length central portion of the second frame portion 17B is linked to the supporting base portion 16. The X-axis sensor 5 is disposed at an inner side of the annular portion 17 and is supported by the annular portion 17.

The X-axis sensor 5 has a fixed structure 21 that is fixed to the supporting portion 14 provided inside the cavity 10 and a movable structure 22 that is held such as to be capable of vibrating with respect to the fixed structure 21. The fixed structure 21 and the movable structure 22 are formed to be of the same thickness.

The fixed structure 21 includes a fixed base portion 23 and a plurality of fixed electrodes 24.

The fixed base portion 23 extends in the X-axis direction along an inner side wall of the first frame portion 17A and is fixed to the supporting portion 14. The fixed base portion 23 has a frame structure of ladder shape in plan view that includes a plurality (two in this preferred embodiment) of main frames that extend in parallel to each other and a plurality of sub frames that are installed between the plurality of main frames.

The plurality of fixed electrodes 24 are formed in a comb-teeth shape on an inner side wall of the fixed base portion 23. The plurality of fixed electrodes 24 are disposed in parallel to each other at equal intervals in the X-axis direction. That is, the plurality of fixed electrodes 24 extend in the +Y direction from the fixed base portion 23.

The movable structure 22 includes a movable base portion 26 and a plurality of movable electrode portions 27.

The movable base portion 26 extends in the X-axis direction along an inner side wall of the third frame portion 17C. Both ends of the movable base portion 26 are connected to the fixed base portion 23 via spring portions that are freely expandable/contractible along the X-axis direction. The spring portions 25 are an example of an “elastic structure” of the present invention.

The movable base portion 26 has a frame structure of ladder shape in plan view that includes a plurality (five in this preferred embodiment) of main frames 26A that extend in parallel to the X-axis direction and a plurality of sub frames 26B that are installed between the plurality of main frames 26A.

The plurality of movable electrode portions 27 are formed in a comb-teeth shape on an inner side wall of the movable base portion 26. The plurality of movable electrode portions 27 are disposed in parallel to each other at equal intervals in the X-axis direction. The plurality of movable electrode portions 27 extend from the movable base portion 26 toward intervals between mutually adjacent fixed electrodes 24. That is, the movable electrode portions 27 of the comb-teeth shape are disposed such as to mesh with the fixed electrodes 24 of the comb-teeth shape without contacting the fixed electrodes 24.

Each movable electrode portion 27 includes a first movable electrode 27A and a second movable electrode 27B that extend in parallel to each other in the −Y direction from respective −Y side ends of a pair of mutually adjacent sub frames 26B within the movable base portion 26B and a plurality of linking portions 27C that link these. A length intermediate portion of each linking portion 27C is constituted of a first isolation coupling portion (insulating layer) 91 that is constituted of silicon oxide (SiO₂). The first movable electrode 27A and the second movable electrode 27B are thereby electrically insulated.

The first movable electrode 27A and the second movable electrode 27B included in the movable electrode portion 27 are an example of a “movable electrode pair” of the present invention.

As shown in FIG. 4, lateral cross-sectional shapes of the fixed electrodes 24 and the movable electrodes 27A and 27B are quadrilateral shapes that are elongate in the Z-axis direction. In other words, the fixed electrodes 24 and the movable electrodes 27A and 27B are of plate shapes with a thickness direction being the X-axis direction.

In the following, a sub frame to which the first movable electrode 27A is connected is referred to as a “first movable sub frame 26Ba” and a sub frame to which the second movable electrode 27B is connected is referred to as a “second movable sub frame 26Bb” at times.

A length intermediate portion of a portion of each main frame 26A that links two adjacent sub frames 26B is constituted of a second isolation coupling portion (insulating layer) 92 that is constituted of silicon oxide. Each sub frame 26B is therefore electrically insulated from other sub frames 26B. Each of the movable electrodes 27A and 27B is electrically insulated from other movable electrodes 27A and 27B by the first isolation coupling portions 91 and the second isolation coupling portions 92.

The first movable electrodes 27A are disposed at the −X side with respect to the second movable electrodes 27B. In a state where an acceleration in the X-axis direction is not acting, an interval between a first movable electrode 27A and the fixed electrode 24 adjacent thereto is equal to an interval between a second movable electrode 27B and the fixed electrode 24 adjacent thereto.

−Y side end portions of the spring portion 25 disposed at the −X side and the spring portion 25 disposed at the +X side are mechanically fixed to the fixed base portion 23 via linking frames with which length intermediate portions are constituted of third isolation coupling portions (insulating layer) 93 that are constituted of silicon oxide. The fixed base portion 23 and the spring portions 25 are thus electrically insulated.

A +Y side end of the spring portion 25 disposed at the −X side is mechanically and electrically connected to the first movable sub frame 26Ba at the most −X side. A +Y side end of the spring portion 25 disposed at the +X side is mechanically and electrically connected to the second movable sub frame 26Bb at the most +X side. These spring portions 25 function as springs that support the movable base portion 26 such as to be movable in the X-axis direction and also function as conductive paths.

An unillustrated insulating film is formed on the front surface of the semiconductor substrate 2 including the fixed structure 21 and the movable structure 22. A plurality of unillustrated wirings are formed on a front surface of the insulating film. The plurality of wirings include a first wiring arranged to electrically connect the plurality of fixed electrodes 24 to an electrode pad 4 for the fixed electrodes, a second wiring arranged to electrically connect the plurality of first movable electrodes 27A to an electrode pad 4 for the first movable electrodes, and a third wiring arranged to electrically connect the plurality of second movable electrodes 27B to an electrode pad 4 for the second movable electrodes.

The second wiring includes a wiring arranged to electrically connect the plurality of first movable sub frames 26Ba to each other and a wiring arranged to electrically connect the spring portion 25 at the −X side to the electrode pad 4 for the first movable electrodes.

The third wiring includes a wiring arranged to electrically connect the plurality of second movable sub frames 26Bb to each other and a wiring arranged to electrically connect the spring portion 25 at the +X side to the electrode pad 4 for the second movable electrodes.

In this preferred embodiment, a length of the X-axis sensor 5 in each of the X-axis direction and the Y-axis direction is, for example, approximately 300 μm. A Z-axis direction length from a +Z side surface of the X-axis sensor 5 to an inner surface (+Z side surface) of the bottom wall 12 (see FIG. 4) of the semiconductor substrate 2 is, for example, approximately 50 μm. A Z-axis direction length from the +Z side surface of the X-axis sensor 5 to an outer surface (−Z side surface) of the bottom wall 12 of the semiconductor substrate 2 is, for example, approximately 200 μm to 300 μm. Also, a length in the Z-axis direction of each of the fixed electrodes 24, the first movable electrodes 27A, and the second movable electrodes 27B is, for example, approximately 15 μm to 30 μm.

With the X-axis sensor 5, when an acceleration in the X-axis direction acts, the movable base portion 26 supported by the two spring portions 25 vibrates in the X-axis direction. Thereby, each of the first movable electrodes 27A and the second movable electrodes 27B extending from the movable base portion 26 also vibrates in the X-axis direction between two mutually adjacent fixed electrodes 24. When the movable base portion 26 moves in the +X direction, each first movable electrode 27A moves to a position away from the adjacent fixed electrode 24 and each second movable electrode 27B moves to a position approaching the adjacent fixed electrode 24. Oppositely, when the movable base portion 26 moves in the −X direction, each first movable electrode 27A moves to a position approaching the adjacent fixed electrode 24 and each second movable electrode 27B moves to a position away from the adjacent fixed electrode 24.

Thereby, a facing distance dl between the first movable electrode 27A and the fixed electrode 24 adjacent thereto and a facing distance d2 between the second movable electrode 27B and the fixed electrode 24 adjacent thereto change. Then, by detecting a change in an electrostatic capacitance C1 between the first movable electrode 27A and the fixed electrode 24 due to the change in the facing distance d1 and a change in an electrostatic capacitance C2 between the second movable electrode 27B and the fixed electrode 24 due to the change in the facing distance d2, the acceleration in the X-axis direction is detected.

Referring to FIG. 3 and FIG. 5A, the spring portion 25 at the −X side is arranged from a rectilinear portion 30 that extends in the Y-axis direction. The rectilinear portion 30 includes two rectilinear frames 31 that extend in parallel to the Y-axis direction and a plurality of reinforcing frames 32 that are installed between the rectilinear frames 31. The reinforcing frames 32 include a first reinforcing frame 32A that links −Y direction ends of the two rectilinear frames 31 to each other, a second reinforcing frame 32B that links +Y direction ends of the two rectilinear frames 31 to each other, and a plurality of third reinforcing frames 32C that link length direction intermediate portions of the two rectilinear frames 31 to each other.

A first connection portion 33 that extends in the +X direction is linked to a +X side end of the first reinforcing frame 32A. A second connection portion 34 that extends in the +X direction is linked to a +X side end of the second reinforcing frame 32B. The −Y side end of the spring portion 25 (rectilinear portion 30) is mechanically connected to the fixed base portion 23 via the first connection portion 33. The +Y side end of the spring portion 25 (rectilinear portion 30) is mechanically and electrically connected to the first movable sub frame 26Ba via the second connection portion 34.

The spring portion 25 disposed at the +X side has a planar shape that is line symmetrical to the spring portion 25 at the −X side in relation to a straight line passing through a center between the spring portion 25 at the −X side and the spring portion 25 at the +X side and extending in the Y-axis direction. Therefore, in the spring portion 25 at the +X side, a first connection portion 33 that extends in the −X direction is linked to a −X side end of the first reinforcing frame 32A and a second connection portion 34 that extends in the −X direction is linked to a −X side end of the second reinforcing frame 32B. The −Y side end of the spring portion 25 (rectilinear portion 30) at the +X side is mechanically connected to the fixed base portion 23 via the first connection portion 33. The +Y side end of the spring portion 25 (rectilinear portion 30) at the +X side is mechanically and electrically connected to the second movable sub frame 26Bb via the second connection portion 34.

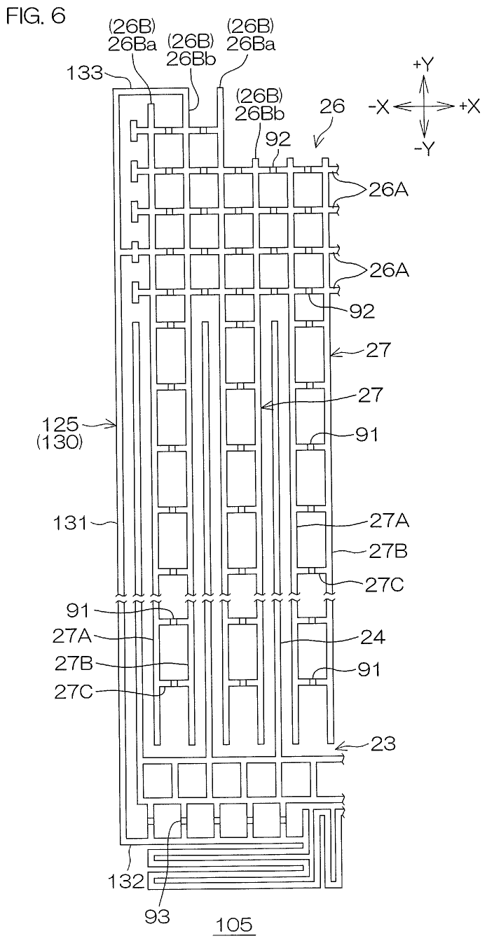

FIG. 6 is an enlarged illustrative plan view of principal portions showing a reference example of the X-axis sensor. In FIG. 6, portions corresponding to respective portions in FIG. 3 described above are indicated with the same reference signs attached as in FIG. 3. FIG. 5D is an enlarged illustrative plan view showing a spring portion used in the X-axis sensor according to the reference example shown in FIG. 6.

A spring portion 125 at the −X side used in an X-axis sensor 105 according to the reference example is arranged from a rectilinear portion 131 that is constituted of a single rectilinear frame extending in the Y-axis direction. A first connection portion 132 that extends in the +X direction from a −Y direction end of the rectilinear portion 131 is linked to the −Y direction end of the rectilinear portion 131. A second connection portion 133 of hook shape in plan view that extends in the +X direction from a +Y direction end of the rectilinear portion 131 and thereafter extends in the −Y direction is linked to the +Y direction end of the rectilinear portion 131. A −Y side end of the spring portion 125 (rectilinear portion 131) is mechanically connected to the fixed base portion 23 via the first connection portion 132. A +Y side end of the spring portion 125 (rectilinear portion 131) is mechanically and electrically connected to the second movable sub frame 26Bb via the second connection portion 133.

A spring portion 125 disposed at the +X side has a planar shape that is line symmetrical to the spring portion 125 at the −X side in relation to a straight line passing through a center between the spring portion 125 at the −X side and the spring portion 125 at the −X side and extending in the Y-axis direction. In the spring portion 125 at the +X side, a first connection portion 132 that extends in the −X direction is linked to a −Y side end of a rectilinear portion 131 constituted of a single rectilinear frame and a second connection portion 133 of hook shape in plan view that extends in the −X direction and thereafter extends in the −Y direction is linked to a +Y side end of the rectilinear portion 131. A −Y side end of the spring portion 125 (rectilinear portion 131) at the +X side is mechanically connected to the fixed base portion 23 via the first connection portion 132. A +Y side end of the spring portion 125 (rectilinear portion 131) at the +X side is mechanically and electrically connected to the first movable sub frame 26Ba via the second connection portion 133.

There is a limit to a width of a frame (rectilinear frame) used in a spring portion. Therefore, with the spring portion 25 used in the X-axis sensor 5 of this preferred embodiment, a width of the rectilinear portion 30 can be made large in comparison to the spring portion 125 of the X-axis sensor 105 according to the reference example. That is, a width W1 (see FIG. 5A) of the rectilinear portion 30 of the spring portion 25 can be made greater than a width W2 (see FIG. 5D) of the rectilinear portion 131 of the spring portion 125. A resonance frequency of a movable portion of the X-axis sensor 5 can thereby be increased. A range of detectable acceleration can thereby be made wider.

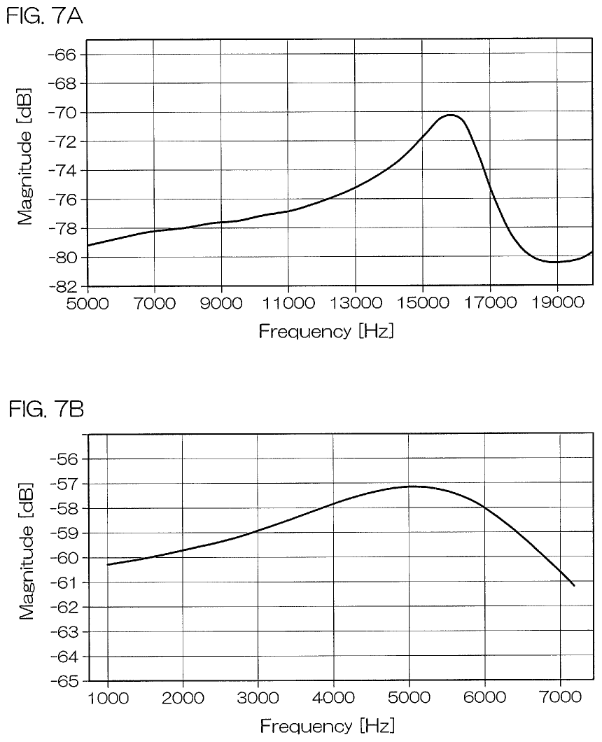

FIG. 7A is a graph showing a relationship of frequency and amplitude of vibration of the X-axis sensor 5 of this preferred embodiment. FIG. 7B is a graph showing a relationship of frequency and amplitude of vibration of the X-axis sensor 105 according to the reference example.

From FIG. 7A and FIG. 7B, it can be understood that with the X-axis sensor 5 of this preferred embodiment, the resonance frequency of the movable portion can be increased in comparison to the X-axis sensor 105 according to the reference example.

FIG. 5B is an illustrative plan view showing a first modification example of a spring portion disposed at the −X side.

A spring portion 25A at the −X side shown in FIG. 5B is constituted of a rectilinear portion 30A that extends in parallel to the Y-axis direction. The rectilinear portion 30A includes the two rectilinear frames 31 that extend in parallel to Y-axis direction, the first reinforcing frame 32A that links the −Y side ends of the rectilinear frames 31 to each other and the second reinforcing frame 32B that links the +Y side ends of the rectilinear frames 31 to each other. Further, the rectilinear portion 30A includes third reinforcing frames 32D that reinforce the rectilinear frames 31 such that, between the two rectilinear frames 31, spaces of triangular shape are repeated along the rectilinear frames 31.

The first connection portion 33 that extends in the +X direction is linked to the +X side end of the first reinforcing frame 32A. The second connection portion 34 that extends in the +X direction is linked to the +X side end of the second reinforcing frame 32B. A −Y side end of the spring portion 25A (rectilinear portion 30A) is mechanically connected to the fixed base portion 23 via the first connection portion 33. A +Y side end of the spring portion 25A (rectilinear portion 30A) is mechanically and electrically connected to the first movable sub frame 26Ba via the second connection portion 34.

Here, a spring portion 25A disposed at the +X side has a planar shape that is line symmetrical to the spring portion 25A at the −X side in relation to a straight line passing through a center between the spring portion 25A at the −X side and the spring portion 25A at the +X side and extending in the Y-axis direction. Therefore, in the spring portion 25A at the +X side, the first connection portion 33 that extends in the −X direction is linked to the −X side end of the first reinforcing frame 32A and the second connection portion 34 that extends in the −X direction is linked to the −X side end of the second reinforcing frame 32B. A −Y side end of the spring portion 25A (rectilinear portion 30A) at the +X side is mechanically connected to the fixed base portion 23 via the first connection portion 33. A +Y side end of the spring portion 25A (rectilinear portion 30A) at the +X side is mechanically and electrically connected to the second movable sub frame 26Bb via the second connection portion 34.

FIG. 5C is an illustrative plan view showing a second modification example of a spring portion disposed at the −X side.

A spring portion 25B at the −X side shown in FIG. 5C is constituted of a rectilinear portion 30B that extends in parallel to the Y-axis direction. The rectilinear portion 30B includes the three rectilinear frames 31 that extend in parallel to Y-axis direction and a plurality of reinforcing frames 32 installed between the rectilinear frames 31. The reinforcing frames 32 include the first reinforcing frame 32A that links the −Y side ends of the three rectilinear frames 31 to each other, the second reinforcing frame 32B that links the +Y side ends of the three rectilinear frames 31 to each other, and a plurality of the third reinforcing frames 32C that link length direction intermediate portions of the three rectilinear frames 31 to each other.

The first connection portion 33 that extends in the +X direction is linked to the +X side end of the first reinforcing frame 32A. The second connection portion 34 that extends in the +X direction is linked to the +X side end of the second reinforcing frame 32B. A −Y side end of the spring portion 25B (rectilinear portion 30B) is mechanically linked to the fixed base portion 23 via the first connection portion 33. A +Y side end of the spring portion 25B (rectilinear portion 30B) is mechanically and electrically connected to the first movable sub frame 26Ba via the second connection portion 34.

A spring portion 25B disposed at the +X side has a planar shape that is line symmetrical to the spring portion 25B at the −X side in relation to a straight line passing through a center between the spring portion 25B at the −X side and the spring portion 25B at the +X side and extending in the Y-axis direction. Therefore, in the spring portion 25B at the +X side, the first connection portion 33 that extends in the −X direction is linked to the −X side end of the first reinforcing frame 32A and the second connection portion 34 that extends in the −X direction is linked to the −X side end of the second reinforcing frame 32B. A −Y side end of the spring portion 25B (rectilinear portion 30B) at the +X side is mechanically connected to the fixed base portion 23 via the first connection portion 33. A +Y side end of the spring portion 25B (rectilinear portion 30B) at the +X side is mechanically and electrically connected to the second movable sub frame 26Bb via the second connection portion 34.

[3] Y-axis sensor 6

Since the Y-axis sensor 6 has substantially the same arrangement as the X-axis sensor 5 being rotated by 90° in plan view, detailed description thereof shall be omitted. With the Y-axis sensor 6, each of the fixed electrodes 24, the first movable electrodes 27A, and the second movable electrodes 27B extends in the X-axis direction and when an acceleration in the Y-axis direction acts, the movable base portion 26 vibrates in the Y-axis direction. Thereby, each of the first movable electrodes 27A and the second movable electrodes 27B also vibrates in the Y-axis direction between two mutually adjacent fixed electrodes 24. Therefore, by electrically detecting changes in an electrostatic capacitance of a capacitor constituted of the first movable electrode 27A and the adjacent fixed electrode 24 and an electrostatic capacitance of a capacitor constituted of the second movable electrode 27B and the adjacent fixed electrode 24, the acceleration acting in the Y-axis direction can be detected.

[4] Modification Example of X-Axis Sensor

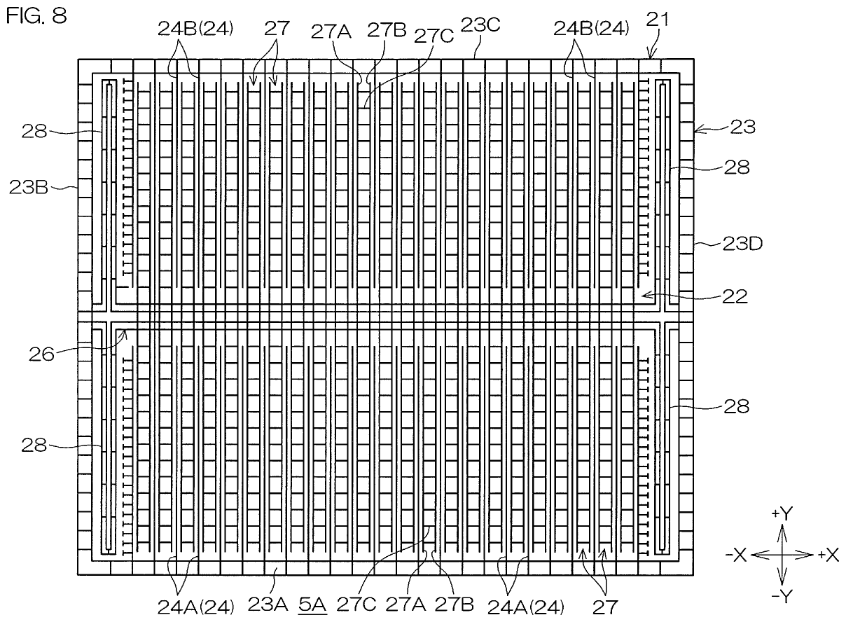

FIG. 8 is an illustrative plan view showing a modification example of an X-axis sensor.

A X-axis sensor 5A has the fixed structure 21 that is fixed to the semiconductor substrate 2 and the movable structure 22 that is held such as to be capable of vibrating with respect to the fixed structure 21. The fixed structure 21 and the movable structure 22 are formed to be of the same thickness. The fixed structure 21 and the movable structure 22 are supported by the semiconductor substrate 2 in a state of floating from the bottom wall of the semiconductor substrate 2.

The fixed structure 21 includes the fixed base portion 23 and a plurality of the fixed electrodes 24.

The fixed base portion 23 is of quadrilateral annular shape in plan view and disposed such as to surround a peripheral edge portion of an arrangement region of the X-axis sensor 5A. The fixed base portion 23 includes a first frame portion 23A at the −Y side, a second frame portion 23B at the −X side, a third frame portion 23C at the +Y side, and a fourth frame portion 23D at the +X side.

A length central portion of the second frame portion 23B and a length central portion of the fourth frame portion 23D are supported by the semiconductor substrate 2.

Each of the frame portions 23A to 23D of the fixed base portion 23 has a frame structure of ladder shape in plan view that includes a plurality (two in the example of FIG. 8) of main frames that extend in parallel to each other and a plurality of sub frames that are installed between the plurality of main frames.

The plurality of fixed electrodes 24 include a plurality of first fixed electrodes 24A that are formed in a comb-teeth shape on an inner side wall of the first frame portion 23A and a plurality of second fixed electrodes 24B that are formed in a comb-teeth shape on an inner side wall of the third frame portion 23C.

The plurality of first fixed electrodes 24A extend from the first frame portion 23A to a vicinity of a central portion in the Y-axis direction of the arrangement region of the X-axis sensor 5A. The plurality of second fixed electrodes 24B extend from the third frame portion 23C to a vicinity of the central portion in the Y-axis direction of the arrangement region of the X-axis sensor 5A. From the first frame portion 23A, the plurality of first fixed electrodes 24A extend in parallel to each other in the +Y direction at equal intervals in the X-axis direction. From the third frame portion 23C, the plurality of second fixed electrodes 24B extend in parallel to each other in the −Y direction at equal intervals in the X-axis direction.

The movable structure 22 includes the movable base portion 26 and a plurality of the movable electrode portions 27.

The movable base portion 26 extends in the X-axis direction at the central portion in the Y-axis direction of the arrangement region of the X-axis sensor 5A and both ends thereof are connected to the fixed base portion 23 via spring portions 28 that are freely expandable/contractible in the X-axis direction. The spring portions 28 are an example of the “elastic structure” of the present invention.

The movable base portion 26 is constituted of a plurality (four in this preferred embodiment) of frames that extend in parallel to the X-axis direction and both ends thereof are connected to the spring portions 28. Two spring portions 28 are provided at each of both ends of the movable base portion 26.

The plurality of movable electrode portions 27 are formed in a comb-teeth shape on each of both side walls of the movable base portion 26. The plurality of movable electrode portions 27 extend across the movable base portion 26 toward intervals between mutually adjacent first fixed electrodes 24A and intervals between mutually adjacent second fixed electrodes 24B.

That is, the movable electrode portions 27 of the comb-teeth shape that extend to the −Y side from the movable base portion 26 are disposed such as to mesh with the first fixed electrodes 24A of the comb-teeth shape without contacting the first fixed electrodes 24A. On the other hand, the movable electrode portions 27 of the comb-teeth shape that extend to the +Y side from the movable base portion 26 are disposed such as to mesh with the second fixed electrodes 24B of the comb-teeth shape without contacting the second fixed electrodes 24B.

Each movable electrode portion 27 includes the first movable electrode 27A and the second movable electrode 27B that extend in parallel to each other in the Y-axis direction at an interval in the X-axis direction and a plurality of the linking portions 27C that link these. A length intermediate portion of each linking portion 27C is constituted of an isolation coupling portion (not shown) that is constituted of silicon oxide.

The first movable electrode 27A and the second movable electrode 27B included in the movable electrode portion 27 are an example of the “movable electrode pair” of the present invention.

The first movable electrodes 27A are disposed at the −X side with respect to the second movable electrodes 27B. In a state where an acceleration in the X-axis direction is not acting, an interval between a first movable electrode 27A and the first fixed electrode 24A or second fixed electrode 24B adjacent thereto is equal to an interval between a second movable electrode 27B and the first fixed electrode 24A or second fixed electrode 24B adjacent thereto.

Each first movable electrode 27A is electrically insulated from other first movable electrodes 27A and the second movable electrodes 27B in the movable base portion 26. Each second movable electrode 27B is electrically insulated from other second movable electrodes 27B and the first movable electrodes 27A in the movable base portion 26.

The two spring portions 28 disposed at the −X side are connected to the first movable electrodes 27A that are disposed at the most −X side in the movable base portion 26. The two spring portions 28 disposed at the +X side are connected to the second movable electrodes 27B that are disposed at the most +X side in the movable base portion 26. The four spring portions 28 function as springs that support the movable base portion 26 such as to be movable in the X-axis direction and also function as conductive paths.

An unillustrated insulating film is formed on the front surface of the semiconductor substrate 2 including the fixed structure 21 and the movable structure 22. Unillustrated wirings are formed on a front surface of the insulating film. The wirings include a first wiring arranged to electrically connect the plurality of first fixed electrodes 24A and the plurality of second fixed electrodes 24B to the electrode pad 4 for the fixed electrodes, a second wiring arranged to electrically connect the plurality of first movable electrodes 27A to the electrode pad 4 for the first movable electrodes, and a third wiring arranged to electrically connect the plurality of second movable electrodes 27B to the electrode pad 4 for the second movable electrodes.

With the X-axis sensor 5A, when an acceleration in the X-axis direction acts, the movable base portion 26 supported by the four spring portions 28 vibrates in the X-axis direction. Thereby, each of the first movable electrodes 27A and the second movable electrodes 27B extending from the movable base portion 26 also vibrates in the X-axis direction between two mutually adjacent first fixed electrodes 24A or between two mutually adjacent second fixed electrodes 24B.

By detecting a change in an electrostatic capacitance between a first movable electrode 27A and the first fixed electrode 24A or the second fixed electrode 24B adjacent thereto and a change in an electrostatic capacitance between a second movable electrode 27B and the first fixed electrode 24A or the second fixed electrode 24B adjacent thereto, the acceleration in the X-axis direction is detected.

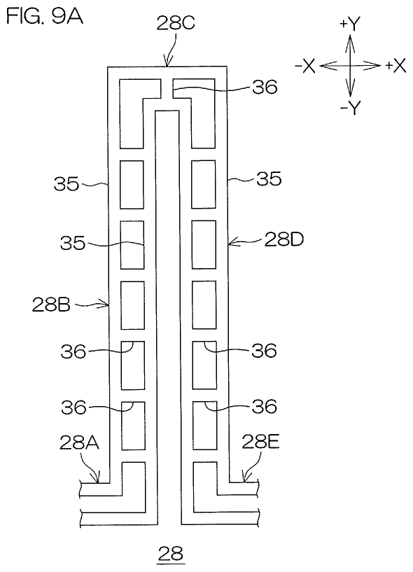

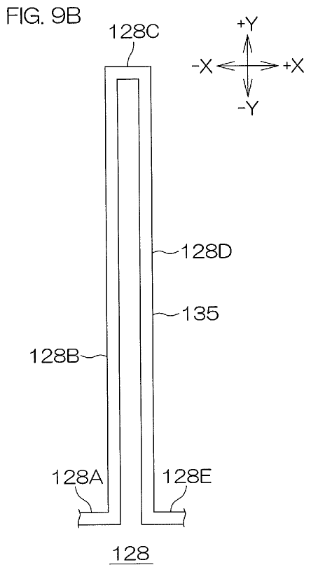

FIG. 9A is an illustrative plan view showing the spring portion 28 disposed at the +Y side of the −X side.

Referring to FIG. 8 and FIG. 9A, the spring portion 28 has, in plan view, a vertically-long U shape that opens downward. Specifically, the spring portion 28 includes, in plan view, a first rectilinear portion 28B that extends in the Y-axis direction, a second rectilinear portion 28D that is disposed at an interval to the +X side from the first rectilinear portion 28B and extends in parallel to the first rectilinear portion 28B, and a third rectilinear portion (linking portion) 28C that links +Y direction end portions of the first rectilinear portion 28B and the second rectilinear portion 28D to each other. The spring portion 28 further includes a first connection portion 28A that extends in the −X direction from a −Y side end of the first rectilinear portion 28B and a second connection portion 28E that extends in the +X direction from a −Y side end of the second rectilinear portion 28D.

The first connection portion 28A, the first rectilinear portion 28B, the third rectilinear portion 28C, the second rectilinear portion 28D, and the second connection portion 28E each include two rectilinear frames 35 that extend in parallel to each other. In each of the first rectilinear portion 28B, the third rectilinear portion 28C, and the second rectilinear portion 28D, one or a plurality of reinforcing frames 36 that are installed between the rectilinear frames 35 are included.

A first end portion of the spring portion 28 (−Y side end portion of the first rectilinear portion 28B) is mechanically connected to the second frame portion 23B of the fixed base portion 23 via the first connection portion 28A. A second end portion of the spring portion 28 (−Y side end portion of the second rectilinear portion 28D) is mechanically and electrically connected to the movable base portion 26 via the second connection portion 28E.

The spring portion 28 disposed at the −Y side of the −X side has a planar shape that is line symmetrical to the spring portion 28 at the +Y side of the −X side in relation to a straight line passing through a center between the spring portion 28 at the +Y side of the31 X side and the spring portion 28 at the −Y side of the −X side and extending in the X-axis direction. A first end portion of that spring portion 28 (+Y side end portion of the first rectilinear portion 28B) is mechanically connected to the second frame portion 23B of the fixed base portion 23 via the first connection portion 28A. A second end portion of that spring portion 28 (+Y side end portion of the second rectilinear portion 28D) is mechanically and electrically connected to the movable base portion 26 via the second connection portion 28E.

The two spring portions 28 at the +X side have a planar shape that is line symmetrical to the two spring portions 28 at the −X side in relation to a straight line passing through a center between the two spring portions 28 at the −X side and the two spring portions 28 at the +X side and extending in the Y-axis direction.

FIG. 9B is an illustrative plan view showing a reference example of a spring portion disposed at the +Y side of the −X side.

An overall shape of a spring portion 128 of the reference example is similar to the spring portion 28 of FIG. 9A and is constituted of a first connection portion 128A, a first rectilinear portion 128B, a third rectilinear portion (linking portion) 128C, a second rectilinear portion 128D, and a second connection portion 128E. However, with the spring portion 128 of the reference example, the respective portions 128A to 128E are each arranged from a single rectilinear frame 135.

There is a limit to a width of a frame (rectilinear frame) used in a spring portion. Therefore, with the spring portion 28 used in the X-axis sensor 5A according to the modification example, widths of the rectilinear portions 28B to 28D can be made large in comparison to the spring portion 128 of the reference example. That is, the widths of the rectilinear portions 28B to 28D of the spring portion 28 can be made greater than the widths of the rectilinear portions 128B to 128D of the spring portion 128. Thereby, with the X-axis sensor 5A according to the modification example, a resonance frequency of a movable portion can be increased in comparison to an X-axis sensor in which the spring portion 128 of the reference example is used. A range of detectable acceleration can thereby be made wider.

[5] Z-Axis Sensor

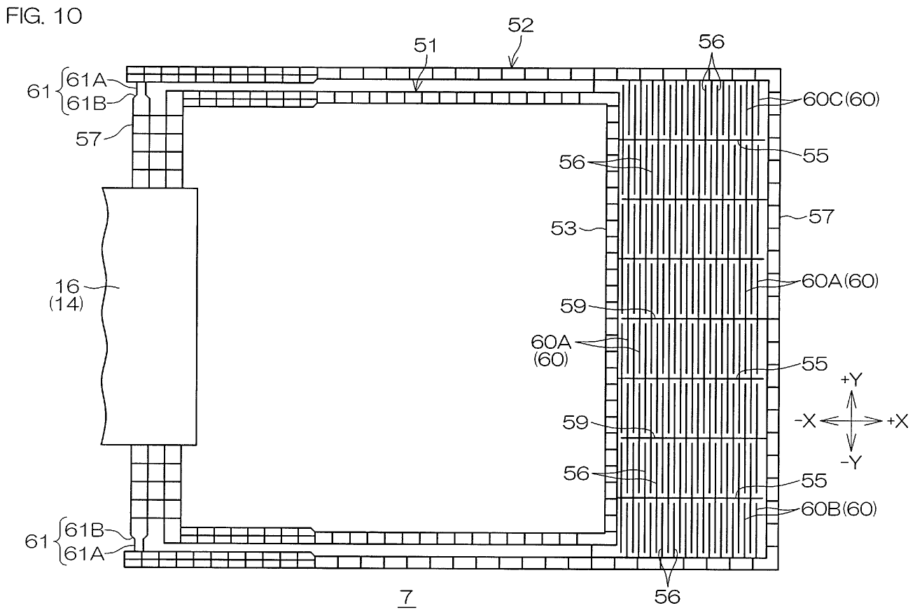

Next, the arrangement of a Z-axis sensor shall be described with reference to FIG. 2, FIG. 4, and FIG. 10 to FIG. 12.

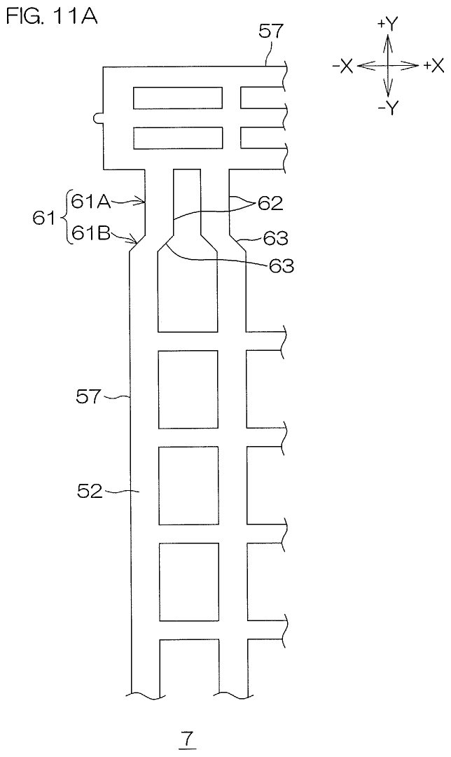

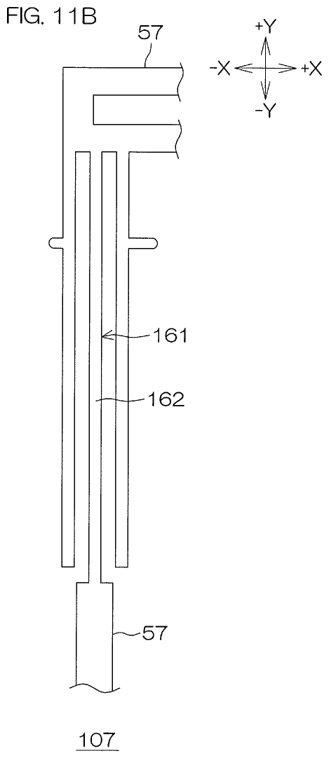

FIG. 10 is an illustrative plan view showing the Z-axis sensor. FIG. 11A is an enlarged plan view of principal portions of FIG. 10.

As mentioned above, the semiconductor substrate 2 has the cavity 10 (see FIG. 4) in its interior. At a front surface portion of the semiconductor substrate 2, the Z-axis sensors 7 that are supported by the supporting portion 14 in a state of floating with respect to the bottom wall 12 (see FIG. 4) of the semiconductor substrate 2 are disposed such as to surround the X-axis sensor 5 and the Y-axis sensor 6 respectively.

Each Z-axis sensor 7 has a fixed structure 51 that is fixed to the supporting portion 14 (supporting base portion 16) provided inside the cavity 10 and a movable structure 52 that is held such as to be capable of vibrating with respect to the fixed structure 51. The fixed structure 51 and the movable structure 52 are formed to be of the same thickness.

With the Z-axis sensor 7 shown in FIG. 10, the fixed structure 51 is disposed such as to surround the X-axis sensor 5 (more specifically, the annular portion 17 of the supporting portion 14 described above) and the movable structure 52 is disposed such as to further surround the fixed structure 51. The fixed structure 51 and the movable structure 52 are connected integrally to a side wall at the −Y side and a side wall at the +Y side of the supporting base portion 16.

Although not illustrated, with the Z-axis sensor 7 that is disposed such as to surround the Y-axis sensor 6, the movable structure 52 is disposed such as to surround the Y-axis sensor 6 and the fixed structure 51 is disposed such as to further surround the movable structure 52.

Returning to FIG. 10, the fixed structure 51 includes a fixed base portion 53 of quadrilateral annular shape in plan view that is fixed to the supporting base portion 16. The fixed base portion 53 includes a frame portion at the −Y side, a frame portion at the −X side, a frame portion at the +Y side, and a frame portion at the +X side. The fixed structure 51 further includes a fixed electrode structure that is provided at the +X side frame portion of the fixed base portion 53.

Each frame portion of the fixed base portion 53 has a frame structure of ladder shape in plan view that includes a plurality of main frames of rectilinear shape that extend in parallel to each other and a plurality of sub frames that are installed between the plurality of main frames.

The fixed electrode structure has a plurality of fixed backbone portions 55 and a plurality of fixed electrodes 56. The plurality of fixed backbone portions 55 are aligned in a comb-teeth shape on an outer side wall of the +X side frame portion of the fixed base portion 53. The plurality of fixed backbone portions 55 extend in parallel to each other in the +X direction at equal intervals in the Y-axis direction from the +X side frame portion of the fixed base portion 53.

The plurality of fixed electrodes 56 are formed in a comb-teeth shape on each of both side walls of each fixed backbone portion 55. The fixed electrodes 56 of the comb-teeth shape extend in parallel to each other in the Y-axis direction at equal intervals in the X-axis direction respectively from both side walls of the fixed backbone portion 55.

The movable structure 52 includes a movable base portion 57 of quadrilateral annular shape in plan view. The movable base portion 57 includes a frame portion at the −Y side (−Y side rectilinear portion), a frame portion at the −X side (−X side rectilinear portion), a frame portion at the +Y side (+Y side rectilinear portion), and a frame portion at the +X side (+X side rectilinear portion). However, the frame portion at the −X side (−X side rectilinear portion) of the movable base portion 57 is linked to the frame portion at the −X side of the fixed base portion 53 and therefore, the frame portion at the −X side (−X side rectilinear portion) of the movable base portion 57 can be regarded as being a portion of the fixed base portion 53. In this case, the movable base portion 57 is constituted of the −Y side rectilinear portion, the +Y side rectilinear portion, and the +X side rectilinear portion that links +X side ends of these to each other.

The movable structure 52 further includes a movable electrode structure that is formed on the +X side frame portion (+X side rectilinear portion), a +X side end portion of the −Y side frame portion (−Y side rectilinear portion), and a +X side end portion of the +Y side frame portion (+Y side rectilinear portion) of the movable base portion 57.

The movable electrode structure includes a plurality of movable backbone portions 59 and a plurality of movable electrodes 60. The plurality of movable backbone portions 59 are formed in a comb-teeth shape on an inner side wall of the +X side frame portion of the movable base portion 57. The plurality of movable backbone portions 59 extend from the +X side frame portion of the movable base portion 57 toward intervals between mutually adjacent fixed backbone portions 55. That is, the movable backbone portions 59 of the comb-teeth shape are disposed such as to mesh with the fixed backbone portions 55 of the comb-teeth shape without contacting the fixed backbone portions 55.

The plurality of movable electrodes 60 include a plurality of first movable electrodes 60A that are formed in a comb-teeth shape on both side walls of the movable backbone portions 59, second movable electrodes 60B that are formed in a comb-teeth shape on an inner side wall of the −Y side frame portion of the movable base portion 57, and third movable electrodes 60C that are formed in a comb-teeth shape on an inner side wall of the +Y side frame portion of the movable base portion 57.

The plurality of first movable electrodes 60A extend from both side walls of the movable backbone portions 59 toward intervals between mutually adjacent fixed electrodes 56. The plurality of second movable electrodes 60B extend from the −Y side frame portion of the movable base portion 57 toward intervals between mutually adjacent fixed electrodes 56. The plurality of third movable electrodes 60C extend from the +Y side frame portion of the movable base portion 57 toward intervals between mutually adjacent fixed electrodes 56.

That is, the plurality of movable electrodes 60 (60A to 60C) extend in the Y-axis direction. The movable electrodes 60 of the comb-teeth shape are disposed such as to mesh with the fixed electrodes 24 of the comb-teeth shape without contacting the fixed electrodes 56.

Each frame portion of the movable base portion 57 has a frame structure of ladder shape in plan view that includes a plurality of main frames of rectilinear shape that extend in parallel to each other and a plurality of sub frames that are installed between the plurality of main frames. A −Y side end portion of the −X side frame portion of the movable base portion 57 and a −X side end portion of the −Y side frame portion of the movable base portion 57 are linked via a spring portion 61 at the −Y side. Similarly, a +Y side end portion of the −X side frame portion of the movable base portion 57 and a −X side end portion of the +Y side frame portion of the movable base portion 57 are linked via a spring portion 61 at the +Y side. The spring portions 61 are an example of the “elastic structure” of the present invention.

As shown in FIG. 10 and FIG. 11A, the spring portion 61 at the +Y side is constituted of a rectilinear portion 61A that extends in the Y-axis direction and a tapered portion 61B that is formed at a −Y side end of the rectilinear portion 61A.

The rectilinear portion 61A is constituted of two rectilinear frames 62 that extend in parallel to each other in the Y-axis direction. The tapered portion 61B is constituted of two inclined frames 63 that extend obliquely outward with respect to the two rectilinear frames 62 from respective −Y side ends of the two rectilinear frames 62 such that an interval between each other widens gradually.

A first end portion (−Y side end portions of the tapered portion 61B) of the spring portion 61 is supported by the supporting base portion 16 via the −X side frame portion of the movable base portion 57. A second end portion (+Y side end portions of the rectilinear portion 61A) of the spring portion 61 is mechanically and electrically connected to the −X side end portion of the +Y side frame portion of the movable base portion 57.

The spring portion 61 at the −Y side has a planar shape that is line symmetrical to the spring portion 61 at the +Y side in relation to a straight line passing through a center between the spring portion 61 at the +Y side and the spring portion 61 at the −Y side and extending in the X-axis direction. The spring portion 61 at the −Y side is constituted of a rectilinear portion 61A that extends in the Y-axis direction and a tapered portion 61B that is formed at a +Y side end of the rectilinear portion 61A.

The rectilinear portion 61A is constituted of two rectilinear frames 62 that extend in parallel to each other in the Y-axis direction. The tapered portion 61B is constituted of two inclined frames 63 that extend obliquely outward with respect to the two rectilinear frames 62 from respective +Y side ends of the two rectilinear frames 62 such that an interval between each other widens gradually.

A first end portion (+Y side end portions of the tapered portion 61B) of the spring portion 61 at the −Y side is supported by the supporting base portion 16 via the −X side frame portion of the movable base portion 57. A second end portion (−Y side end portions of the rectilinear portion 61A) of the spring portion 61 at the −Y side is mechanically and electrically connected to the −X side end portion of the −Y side frame portion of the movable base portion 57. The two spring portions 61 function as springs for making the movable electrode 60 movable in the Z-axis direction.

That is, with the Z-axis sensor 7, the spring portions 61 distort elastically and by the movable base portion 57 vibrating as it were a pendulum in a direction of approaching and a direction of separating away the bottom wall 12 (see FIG. 4) of the semiconductor substrate 2 with the spring portions 61 as support points, the movable electrodes 60 that are meshed in comb-teeth shape with the fixed electrodes 56 vibrate in the Z-axis direction.

When an acceleration in the Z-axis direction acts on the Z-axis sensor 7, the movable electrodes 60 move in the Z-axis direction. Thereby, an area of regions in which facing surfaces of the movable electrodes 60 and the fixed electrodes 56 overlap changes. By electrically detecting a change in electrostatic capacitance due to the change in the area, the acceleration acting in the Z-axis direction can be detected.

In the following, the Z-axis sensor 7 disposed such as to surround the X-axis sensor 5 is referred to at times as a “first Z-axis sensor 7A” and the Z-axis sensor 7 disposed such as to surround the Y-axis sensor 6 is referred to at times as a “second Z-axis sensor 7B.”

In this preferred embodiment, with the first Z-axis sensor 7A, the fixed electrode structure of the fixed structure 51 that is disposed at the inner side of the movable structure 52 is warped such as to sag toward the −Z side due to influence of an unillustrated silicon oxide film formed on a front surface of the fixed base portion 53.

On the other hand, with the second Z-axis sensor 7B, the movable electrode structure of the movable structure 52 that is disposed at the inner side of the fixed structure 51 is warped such as to sag toward the −Z side due to influence of an unillustrated silicon oxide film formed on a front surface of a movable base portion.

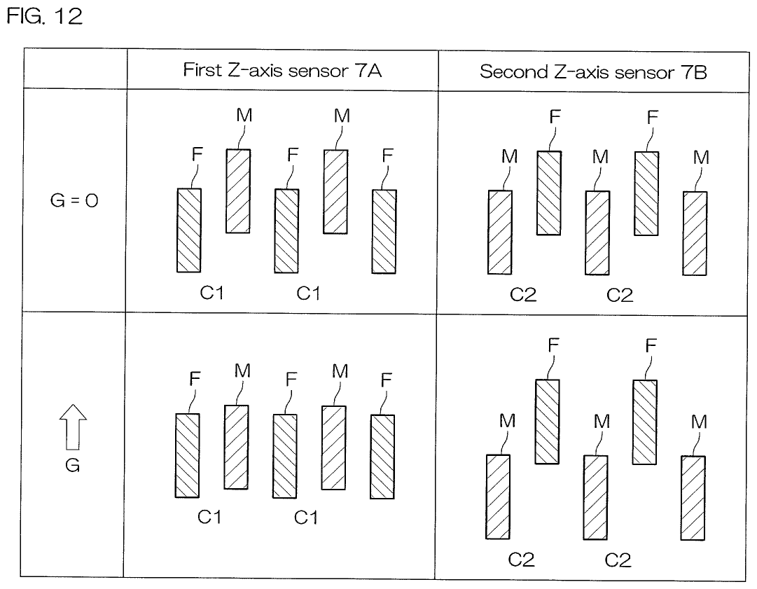

FIG. 12 is a schematic view showing positional relationships in the Z-axis direction of the fixed electrodes and the movable electrodes of the Z-axis sensors when an acceleration in the Z-axis direction is not acting and positional relationships in the Z-axis direction of the fixed electrodes and the movable electrodes of the Z-axis sensors when an acceleration in the Z-axis direction acts. In FIG. 12, a fixed electrode is represented by F and a movable electrode is represented by M.

At the upper left of FIG. 12, the positional relationship in the Z-axis direction of the fixed electrodes F and the movable electrodes M in the first Z-axis sensor 7A when an acceleration in the Z-axis direction is not acting on the acceleration sensor 1 is shown.

At the upper right of FIG. 12, the positional relationship in the Z-axis direction of the fixed electrodes F and the movable electrodes M in the second Z-axis sensor 7B when an acceleration in the Z-axis direction is not acting on the acceleration sensor 1 is shown.

At the lower left of FIG. 12, the positional relationship in the Z-axis direction of the fixed electrodes F and the movable electrodes M of the first Z-axis sensor 7A when an acceleration in the +Z direction acts on the acceleration sensor 1 is shown.

At the lower right of FIG. 12, the positional relationship in the Z-axis direction of the fixed electrodes F and the movable electrodes M of the second Z-axis sensor 7B when the acceleration in the +Z direction acts on the acceleration sensor 1 is shown.

When the acceleration in the +Z direction is not acting on the acceleration sensor 1, the fixed electrodes F are disposed at positions shifted to the −Z side with respect to the movable electrodes M in the first Z-axis sensor 7A. On the other hand, in the second Z-axis sensor 7B, the movable electrodes M are disposed at positions shifted to the −Z side with respect to the movable electrodes F.

When the acceleration in the +Z direction acts on the acceleration sensor 1, the movable electrodes M move in the −Z direction with respect to the fixed electrodes F as shown in FIG. 12. Thereby, in the first Z-axis sensor 7A, an electrostatic capacitance Cl between the fixed electrodes F and the movable electrodes M increases and in the second Z-axis sensor 7B, an electrostatic capacitance C2 between the fixed electrodes F and the movable electrodes M decreases.

On the other hand, when an acceleration in the −Z direction acts on the acceleration sensor 1, the movable electrodes M move in the +Z direction with respect to the fixed electrodes F. Thereby, in the first Z-axis sensor 7A, the electrostatic capacitance C1 between the fixed electrodes F and the movable electrodes M decreases and in the second Z-axis sensor 7B, the electrostatic capacitance C2 between the fixed electrodes F and the movable electrodes M increases.

By detecting the change in the electrostatic capacitance C1 between the fixed electrodes F and the movable electrodes M in the first Z-axis sensor 7A and the change in the electrostatic capacitance C2 between the fixed electrodes F and the movable electrodes M in the second Z-axis sensor 7B, the acceleration in the Z-axis direction is detected.

FIG. 11B is an enlarged plan view of principal portions showing a reference example of a Z-axis sensor.

In FIG. 11B, portions corresponding to respective portions in FIG. 11A described above are indicated with the same reference signs attached as in FIG. 11A.

A Z-axis sensor 107 shown in FIG. 11B has a structure similar to the Z-axis sensor 7 described above but differs from the Z-axis sensor 7 described above in regard to a spring portion and a structure in a vicinity thereof. A −X side frame portion of the movable base portion 57 is arranged from a single main frame. A +Y side end portion of a −X side frame portion of the movable base portion 57 is linked to a +Y side frame portion of the movable base portion 57 via a spring portion 161 at the +Y side and a −Y side end portion of the −X side frame portion of the movable base portion 57 is linked to a −Y side frame portion of the movable base portion 57 via a spring portion 161 at the −Y side of the same arrangement as the spring portion 161 at the +Y side.

The spring portion 161 at the +Y side is arranged from a rectilinear portion 162 constituted of a single rectilinear frame that extends in the Y-axis direction. A first end portion (−Y side end portion of the rectilinear portion 162) of the spring portion 161 is supported by the supporting base portion 16 via the −X side frame portion of the movable base portion 57. A second end portion (+Y side end portion of the rectilinear portion 162) of the spring portion 161 is mechanically and electrically connected to the +Y side frame portion of the movable base portion 57.

The spring portion 161 at the −Y side has a planar shape that is line symmetrical to the spring portion 161 at the +Y side in relation to a straight line passing through a center between the spring portion 161 at the +Y side and the spring portion 161 at the −Y side and extending in the X-axis direction. The spring portion 161 at the −Y side is arranged from a rectilinear portion 162 constituted of a single rectilinear frame that extends in the Y-axis direction. A first end portion (+Y side end portion of the rectilinear portion 162) of the spring portion 161 at the −Y side is supported by the supporting base portion 16 via the −X side frame portion of the movable base portion 57. A second end portion (−Y side end portion of the rectilinear portion 162) of the spring portion 161 is mechanically and electrically connected to the −Y side frame portion of the movable base portion 57.

There is a limit to a width of a frame used in a spring portion. Therefore, with the spring portion 61 used in the Z-axis sensor 7 of this preferred embodiment, a width of the rectilinear portion 61A can be made large in comparison to the spring portion 161 used in the Z-axis sensor 107 of the reference example. That is, the width of the rectilinear portion 61A of the spring portion 61 can be made greater than the width of the rectilinear portion 162 of the spring portion 161. Thereby, with the Z-axis sensor 7 of this preferred embodiment, a resonance frequency of a movable portion can be increased in comparison to the Z-axis sensor 107 of the reference example. A range of detectable acceleration can thereby be made wider.

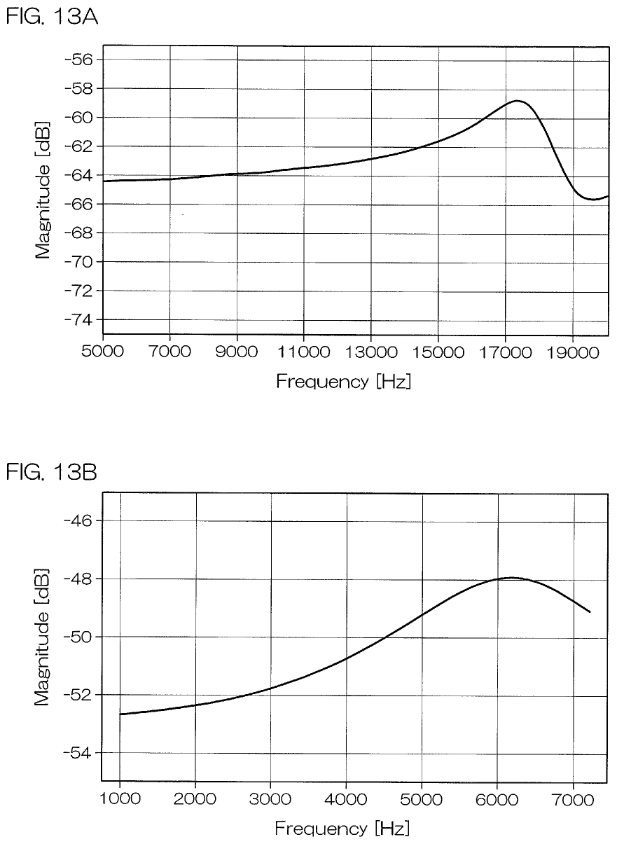

FIG. 13A is a graph showing a relationship of frequency and amplitude of vibration of the Z-axis sensor 7 of this preferred embodiment. FIG. 13B is a graph showing a relationship of frequency and amplitude of vibration of the Z-axis sensor 107 according to the reference example.

From FIG. 13A and FIG. 13B, it can be understood that with the Z-axis sensor 7 of this preferred embodiment, the resonance frequency of the movable portion can be increased in comparison to the Z-axis sensor 107 according to the reference example.

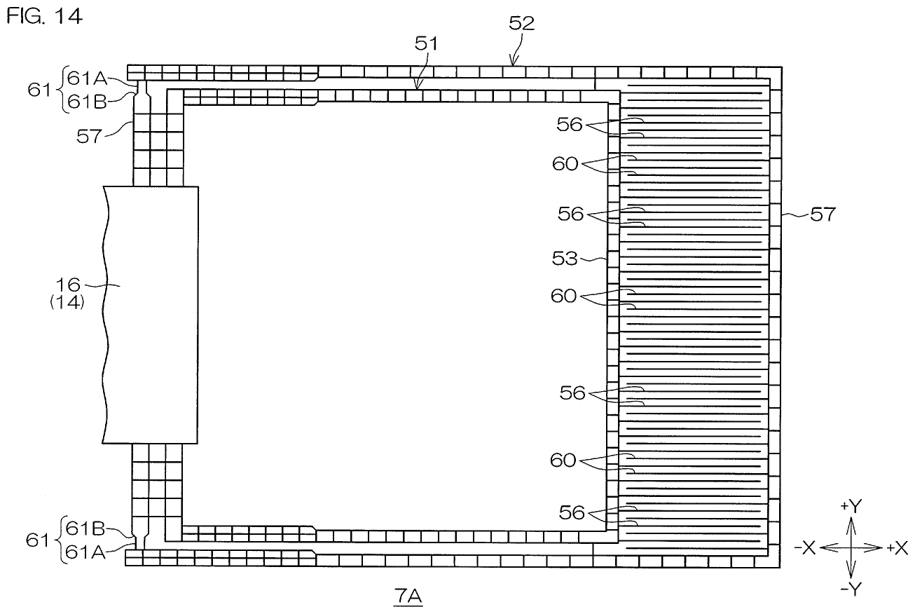

FIG. 14 is an illustrative plan view showing a modification example of a Z-axis sensor. In FIG. 14, portions corresponding to respective portions in FIG. 10 described above are indicated with the same reference signs attached as in FIG. 10.

The Z-axis sensor 7A of FIG. 14 differs from the Z-axis sensor 7 of FIG. 10 in the arrangement of the fixed electrode structure and the movable electrode structure. With the Z-axis sensor 7A of FIG. 14, the fixed electrode structure is constituted of a plurality of the fixed electrodes 56 that are formed in comb-teeth shape on the outer side wall of the +X side frame portion of the fixed base portion 53. The plurality of fixed electrodes 56 extend in parallel to each other in the +X direction at equal intervals in the Y-axis direction from the +X side frame portion of the fixed base portion 53.

With the Z-axis sensor 7A of FIG. 14, the movable electrode structure is constituted of a plurality of the movable electrodes 60 that are formed in comb-teeth shape on the inner side wall of the +X side frame portion of the movable base portion 57. The plurality of movable electrodes 60 extend from the +X side frame portion of the movable base portion 57 toward intervals between mutually adjacent fixed backbone portions 56. The movable electrodes 60 of the comb-teeth shape are disposed such as to mesh with the fixed electrodes 56 of the comb-teeth shape without contacting the fixed electrodes 56.

While preferred embodiments of the present disclosure were described in detail above, these are merely specific examples used to clarify the technical contents of the present disclosure and the present disclosure should not be interpreted as being limited to these specific examples and the scope of the present disclosure is limited only by the appended claims.

1. An acceleration sensor comprising:
a semiconductor substrate that has a cavity formed in an interior;
a fixed structure that includes a fixed electrode supported by the semiconductor substrate in a state of floating with respect to the cavity; and
a movable structure that includes a movable electrode supported by the semiconductor substrate via an elastic structure in a state of floating with respect to the cavity and displacing with respect to the fixed electrode; and
wherein the elastic structure includes a first end portion supported by the semiconductor substrate, a second end portion connected to the movable structure, and an intermediate portion connecting the first end portion and the second end portion and
has a rectilinearly-extending rectilinear portion at least at a portion of the intermediate portion and
the rectilinear portion includes a plurality of rectilinear frames extending in parallel to each other in a direction in which the rectilinear portion extends.

2. The acceleration sensor according to claim 1, wherein the rectilinear portion includes a plurality of reinforcing frames that are installed between the plurality of rectilinear frames included in the rectilinear portion.

3. The acceleration sensor according to claim 1, wherein the rectilinear portion includes a plurality of reinforcing frames that are installed between the plurality of rectilinear frames included in the rectilinear portion such that between the plurality of rectilinear frames, spaces of triangular shape are repeated along the rectilinear frames.

4. The acceleration sensor according to claim 1, wherein the rectilinear portion includes
a first rectilinear portion and a second rectilinear portion that extend in parallel to each other and
a third rectilinear portion that links one ends of the first rectilinear portion and the second rectilinear portion to each other.

5. The acceleration sensor according to claim 4, wherein the first rectilinear portion, the second rectilinear portion, and the third rectilinear portion each include at least one reinforcing frame that is installed between the plurality of rectilinear frames included therein.

6. The acceleration sensor according to claim 1, wherein the rectilinear portion includes a rectilinear portion that is parallel to a direction in which the movable electrode extends.

7. The acceleration sensor according to claim 1, wherein the fixed electrode includes a pair of fixed electrodes that, at an interval in a predetermined first direction, extend in parallel to each other in a second direction orthogonal to the first direction and
the movable electrode includes a pair of movable electrodes that are disposed between the pair of fixed electrodes and, at an interval in the first direction, extend in parallel to each other in the second direction.

8. The acceleration sensor according to claim 1, wherein the fixed electrode includes a plurality of fixed electrodes that are formed in a comb-teeth shape in plan view,
the movable electrode includes a plurality of movable electrode pairs that are formed in a comb-teeth shape in plan view,
the plurality of movable electrode pairs are disposed such as to contactlessly mesh with the plurality of fixed electrodes, and
each movable electrode pair includes two of the movable electrodes that respectively face the fixed electrodes at respective sides of the movable electrode pair and extend in parallel to each other.

9. he acceleration sensor according to claim 7, wherein a lateral cross-sectional shape of the fixed electrode and a lateral cross-sectional shape of the movable electrode are each a quadrilateral shape that is elongate in an up/down direction.

10. The acceleration sensor according to claim 1, wherein the elastic structure includes
one of the rectilinear portion and
a tapered portion that is connected to one end of the rectilinear portion,
the rectilinear portion is constituted of two of the rectilinear frames that are parallel to each other, and
the tapered portion is constituted of two connection frames that extend obliquely outward with respect to the two rectilinear frames from respective one end portions of the two rectilinear frames such that an interval between each other widens gradually.

11. The acceleration sensor according to claim 10, wherein the rectilinear portion is parallel to a direction in which the movable electrode extends or is parallel to a direction that is a direction along a front surface of the semiconductor substrate and orthogonal to the direction in which the movable electrode extends.

12. The acceleration sensor according to claim 10, wherein the fixed electrode includes a plurality of fixed electrodes that are formed in a comb-teeth shape in plan view,
the movable electrode includes a plurality of movable electrodes that are formed in a comb-teeth shape in plan view, and
the plurality of movable electrodes are disposed such as to contactlessly mesh with the plurality of fixed electrodes.

13. The acceleration sensor according to claim 12, wherein a lateral cross-sectional shape of the fixed electrode and a lateral cross-sectional shape of the movable electrode are each a quadrilateral shape that is elongate in an up/down direction.

14. The acceleration sensor according to claim 13, wherein one of either of the fixed electrode and the movable electrode is disposed in a state of being shifted downward with respect to the other.

15. The acceleration sensor according to claim 2, wherein the rectilinear portion includes a rectilinear portion that is parallel to a direction in which the movable electrode extends.

3. The acceleration sensor according to claim 3, wherein the rectilinear portion includes a rectilinear portion that is parallel to a direction in which the movable electrode extends.

17. The acceleration sensor according to claim 4, wherein the rectilinear portion includes a rectilinear portion that is parallel to a direction in which the movable electrode extends.

18. The acceleration sensor according to claim 5, wherein the rectilinear portion includes a rectilinear portion that is parallel to a direction in which the movable electrode extends.
